(19) United States
(12) Patent Application Publication
(10) Pub. No.: US 2016/0053386 A1
(43) Pub. Date: Feb. 25, 2016

(54) ETCHING SOLUTION AND ETCHING SOLUTION KIT, ETCHING METHOD USING SAME, AND PRODUCTION METHOD FOR SEMICONDUCTOR SUBSTRATE PRODUCT

(71) Applicant: FUJIFILM Corporation, Tokyo (JP)

(72) Inventors: Atsushi MIZUTANI, Haibara-gun (JP); Tetsuya KAMIMURA, Haibara-gun (JP); Satomi TAKAHASHI, Haibara-gun (JP); Akiko KOYAMA, Haibara-gun (JP)

(73) Assignee: FUJIFILM Corporation, Tokyo (JP)

(21) Appl. No.: 14/928,824

(22) Filed: Oct. 30, 2015

Related U.S. Application Data
(63) Continuation of application No. PCT/JP2014/062067, filed on May 1, 2014.

(30) Foreign Application Priority Data
May 2, 2013 (JP) 2013-097159

(51) Int. Cl. C23F 1/30; H01L 21/465

(52) U.S. Cl. CPC C23F 1/30; H01L 21/465

(57) ABSTRACT

There is provided an etching solution of a semiconductor substrate that includes a first layer containing germanium (Ge) and a second layer containing a specific metal element other than germanium (Ge), the etching solution selectively removing the second layer and including following specific acid compound

Specific acid compound: sulfuric acid (H₂SO₄), nitric acid (HNO₃), phosphoric acid (H₃PO₄), phosphonic acid (H₃PO₃), or organic acid

### CROSS-REFERENCE TO RELATED APPLICATIONS

This application is a Continuation of PCT International Application No. PCT/JP2014/062067 filed on May 1, 2014, which claims priority under 35 U.S.C. §119 (a) to Japanese Patent Application No. 2013-097159 filed in Japan on May 2, 2013. Each of the above applications is hereby expressly incorporated by reference, in its entirety, into the present application.

### BACKGROUND OF THE INVENTION

1. Field of the Invention

The present invention relates to an etching solution and an etching solution kit, an etching method using the same, and a production method for a semiconductor substrate product.

2. Description of the Related Art

An integrated circuit is manufactured in multi-stages of various processing processes. Specifically, in the manufacturing process, deposition of various materials, lithography of a layer whose necessary portion or entire portion is exposed, or etching of the layer is repeated several times. Among these, the etching of a layer of a metal or a metal compound becomes to be an important process. A metal or the like is selectively etched and other layers are required to remain without corroding. In some cases, it is necessary that only a predetermined layer be removed in the form in which layers formed of similar metals and a layer with high corrosivity remain. A wiring in a semiconductor substrate or the size of an integrated circuit becomes smaller and thus the importance of performing etching on a member to accurately remain without corroding has been increasing.

When an example of a field effect transistor is considered, thinning of a silicide layer to be formed on the upper surface of a source and drain region and development of a new material have been strongly demanded along with rapid miniaturization of the field effect transistor. In a salicide process (salicide: self-aligned silicide) of forming the silicide layer, a part of a source region and a drain region formed of silicon and the like formed on a semiconductor substrate and a metal layer attached to the upper surface thereof are annealed. As a metal layer, tungsten (W), titanium (Ti), or cobalt (Co) is used, and more recently nickel (Ni) is being used. In this manner, a silicide layer with low resistance can be formed on the upper side of a source and drain electrode or the like. Currently, in response to further miniaturization, formation of a NiPt silicide layer to which platinum (Pt) which is a noble metal is added has been suggested.

After the salicide process is performed, the metal layer remaining in the region is removed by etching. The etching is normally performed through wet etching and a mixed solution (aqua regia) of hydrochloric acid and nitric acid is used as a liquid chemical. WO2012/125401A discloses an example of using a liquid chemical to which toluenesulfonic acid is added in addition to nitric acid and hydrochloric acid.

### SUMMARY OF THE INVENTION

An object of the present invention is to provide an etching method which improves surface roughness with respect to a layer containing germanium and is capable of selectively removing a second layer containing a specific metal, an etching solution and an etching solution kit used therefor, and a production method for a semiconductor substrate product.

A liquid chemical containing a halogen acid as a main component is used for a treatment liquid of the related art which removes a metal layer, but it is known that the treatment liquid of the related art causes the surface of a layer containing germanium to be roughened (see Comparative Example below). For this reason, when searching for components of a liquid chemical which can improve this phenomenon, it is found that a specific acid compound exerts effects of improvement. The present invention is completed based on such knowledge.

The above-described problems are solved by the following means.

[1] An etching solution of a semiconductor substrate that includes a first layer containing germanium (Ge) and a second layer containing a specific metal element other than germanium (Ge), the etching solution selectively removing the second layer and including following specific acid compound.
Specific acid compound: sulfuric acid (H₂SO₄), nitric acid (HNO₃), phosphoric acid (H₃PO₄), phosphonic acid (H₃PO₃), or organic acid

[2] The etching solution according to [1], in which the concentration of germanium (Ge) of the first layer is 40% by mass or greater.

[3] The etching solution according to [1] or [2], in which a metal element constituting the second layer is selected from nickel platinum (NiPt), titanium (Ti), nickel (Ni), and cobalt (Co).

[4] The etching solution according to any one of [1] to [3], in which the organic acid is inorganic acid which contains a sulfonic acid group, a carboxy group, a phosphoric acid group, a phosphonic acid group, or a hydroxamic acid group.

[5] The etching solution according to any one of [1] to [4], in which the content of those in a small amount series among the acid compounds is in the range of 0.01% by mass to less than 50% by mass and the content of those in a large amount series among the acid compounds is in the range of 25% by mass to 99% by mass.

[6] The etching solution according to any one of [1] to [5], in which the second layer is selectively removed with respect to the first layer and/or the following third layer.
Third layer: layer containing germanium (Ge) and the specific metal element, which is interposed between the first layer and the second layer

[7] The etching solution according to any one of [1] to [6], further containing an oxidant.

[8] An etching solution kit of a semiconductor substrate that includes a first layer containing germanium (Ge) and a second layer containing a metal element, the kit selectively removing the second layer and including: a first liquid containing the following specific acid compound; and a second liquid containing an oxidant.
Specific acid compound: sulfuric acid (H₂SO₄), nitric acid (HNO₃), phosphoric acid (H₃PO₄), phosphonic acid (H₃PO₃), or organic acid

[9] An etching method of a semiconductor substrate includes a first layer containing germanium (Ge) and a second layer containing at least one specific metal element selected from nickel platinum (NiPt), titanium (Ti), nickel (Ni), and cobalt (Co), the method including: bringing an etching solution which contains the following specific acid compound into contact with the second layer and selectively removing the second layer.
Specific acid compound: sulfuric acid (H₂SO₄), nitric acid (HNO₃), phosphoric acid (H₃PO₄), phosphonic acid (H₃PO₃), or organic acid

[10] The etching method according to [9], in which the concentration of germanium (Ge) of the first layer is 40% by mass or greater.

[11] The etching method according to [9] or [10], in which the acid compound is inorganic acid or organic acid which contains a sulfonic acid group, a carboxylic group, a phosphoric acid group, a phosphonic acid group, or a hydroxamic acid group.

[12] The etching method according to any one of [9] to [11], in which the content of a small amount series among the acid compounds is in the range of 0.01% by mass to less than 50% by mass and the content of a large amount series among the acid compounds is in the range of 25% by mass to 99% by mass.

[13] The etching method according to any one of [9] to [12], in which the second layer is selectively removed with respect to the first layer and/or the following third layer.
Third layer: layer containing germanium (Ge) and the specific metal element, which is interposed between the first layer and the second layer

[14] The etching method according to any one of [9] to [13], further including: allowing the semiconductor substrate to rotate and supplying the etching solution through a nozzle from the upper surface of the semiconductor substrate during rotation when the etching solution is provided for the semiconductor substrate.

[15] The etching method according to any one of [9] to [14], in which the temperature of the etching solution at the time of being brought into contact with the second layer is in the range of 20° C. to 80° C.

[16] The etching method according to any one of [9] to [15], in which the etching solution further contains an oxidant, and a first liquid which does not contain the oxidant and a second liquid which contains the oxidant are separated from each other and then stored.

[17] The etching method according to [16], in which the first liquid and the second liquid are mixed with each other at a suitable time when the semiconductor substrate is etched.

[18] A method for manufacturing a semiconductor substrate product that includes a first layer containing germanium (Ge), including: a step of forming at least the first layer and at least one kind of second layer selected from nickel platinum (NiPt), titanium (Ti), nickel (Ni), and cobalt (Co) on the semiconductor substrate; a step of forming a third layer containing components of the first layer and the second layer between both layers by heating the semiconductor substrate; a step of preparing an etching solution containing an acid compound; and a step of bringing the etching solution into contact with the second layer and selectively removing the second layer with respect to the first layer and the third layer.

According to the etching method of the present invention, the etching solution and the etching solution kit used therefor, and the method for manufacturing a semiconductor substrate product, surface roughness with respect to the first layer containing germanium and the silicide layer is improved and thus the second layer containing a specific metal can be selectively removed.

The above-described features, other features, and advantages of the present invention will become more apparent from the following description and the accompanying drawings.

### BRIEF DESCRIPTION OF THE DRAWINGS

FIGS. 1(a), 1(b) and 1(c) each are a sectional view schematically illustrating examples of a process of preparing a semiconductor substrate according to an embodiment of the present invention.

FIGS. 2(A), 2(B), 2(C), 2(D) and 2(E) each are a process view illustrating examples of manufacturing a MOS transistor according to an embodiment of the present invention.

FIG. 3 is a sectional view schematically illustrating a structure of a substrate according to another embodiment of the present invention.

FIG. 4 is a configuration view of a device illustrating a part of a wet etching device according to a preferred embodiment of the present invention.

FIG. 5 is a plan view schematically illustrating a movement trajectory line of a nozzle with respect to a semiconductor substrate according to an embodiment of the present invention.

### DESCRIPTION OF THE PREFERRED EMBODIMENTS

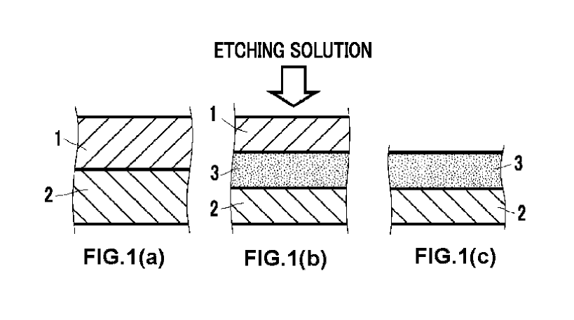

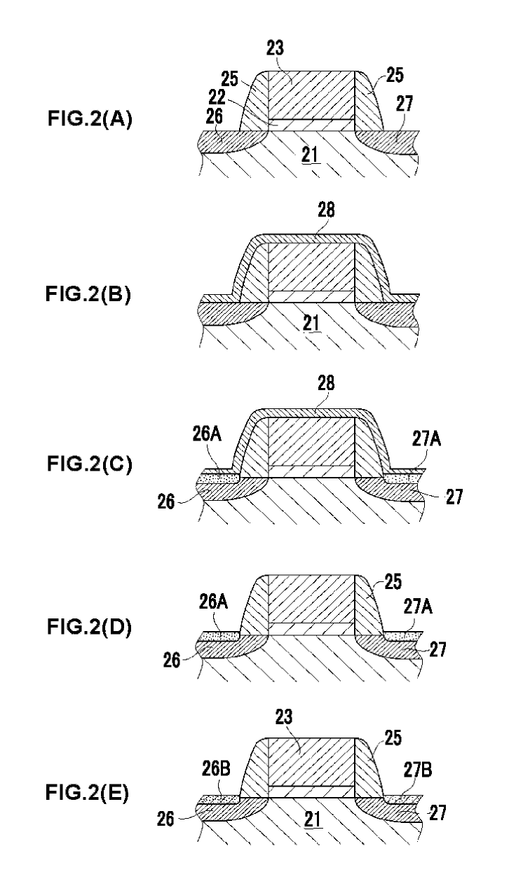

First, preferred embodiments of an etching process according to an etching method of the present invention will be described with reference to FIGS. 1(a) to 1(c) and 2(A) to 2(E).

[Etching Process]

FIGS. 1(a) to 1(c) each are a view illustrating a semiconductor substrate before and after etching is performed. In preparation examples of the present embodiment, a metal layer (second layer) is arranged on the upper surface of a silicon layer (first layer) 2. As the silicon layer (first layer), a SiGe epitaxial layer constituting a source electrode or a drain electrode is used. In the present invention, it is preferable that the silicon layer is a SiGe epitaxial layer or a Ge epitaxial layer in such terms that remarkable effects of the etching solution are exhibited.

As a constituent material of the metal layer (second layer) 1, tungsten (W), titanium (Ti), cobalt (Co), nickel (Ni), or NiPt is exemplified. In order to form a metal layer, a method used for forming such a metal layer can be used. Specifically, a film formation method using chemical vapor deposition (CVD) is exemplified. In this case, the thickness of the metal layer is not particularly limited, but a film whose thickness is in the range of 5 nm to 10 nm is exemplified. In the present invention, it is preferable that a metal layer is a NiPt layer (the content of Pt is preferably in the range of more than 0% by mass to 20% by mass) or a Ni layer (the content of Pt is 0% by mass) in terms such that remarkable effects of the etching solution are exhibited.

The metal layer may contain other elements other than metal elements exemplified above. For example, oxygen or nitrogen to be inevitably mixed thereinto may be present. It is preferable that the amount of inevitable impurities is suppressed within the range of 1 ppt to 10 ppm.

After the metal layer 1 is formed on the upper side of the silicon layer 2 in the above-described process (a), annealing (sintering) is performed and a metal-Si reaction film (third layer: germanium silicide layer) 3 is formed on the interface thereof (process (b)). The annealing may be performed under conditions normally used for manufacturing this kind of element, and a treatment performed in a temperature range of 200° C. to 1000° C. is exemplified. In this case, the thickness of the germanium silicide layer 3 is not particularly limited, but a layer whose thickness is 50 nm or less or a layer whose thickness is 10 nm or less is exemplified. The lower limit is not particularly limited, but the lower limit is substantially 1 nm or greater. The germanium silicide layer is used as a low resistance film and functions as a conductive portion that electrically connects a source electrode, a drain electrode positioned in the lower portion thereof and a wiring arranged in the upper portion thereof. Accordingly, conduction is inhibited when defects or corrosion occurs in the germanium silicide layer and this leads to degradation in quality such as malfunction of an element in some cases. Particularly, the structure of an integrated circuit in the inside of a substrate has been miniaturized and thus even a small amount of damage may have a great impact on the performance of the element. Consequently, it is desired to prevent such defects or corrosion as much as possible.

Next, the remaining metal layer 1 is etched (process (b)→process (c)). In the present embodiment, the etching solution is used at this time and the metal layer 1 is removed by providing the etching solution from the upper side of the metal layer 1 to be in contact with the metal layer 1. The provision of the etching solution will be described below.

The silicon layer 2 is formed of a SiGe epitaxial layer and can be formed through crystal-growth on a silicon substrate having a specific crystallinity according to a chemical vapor deposition (CVD) method. Alternatively, an epitaxial layer formed from a desired crystallinity may be formed according to electron beam epitaxy (MBE).

In order to use the silicon layer as a P type layer, it is preferable that boron (B) whose concentration is in the range of 1×10¹⁴ cm⁻³ to 1×10²¹ cm⁻³ is doped. In order to use the germanium-containing layer as an N type layer, it is preferable that phosphorus (P) whose concentration is in the range of 1 ×10¹⁴ cm⁻³ to 1×10²¹ cm⁻³ is doped.

The Ge concentration in the SiGe epitaxial layer is preferably 20% by mass or greater and more preferably 40% by mass or greater. The upper limit thereof is preferably 100% by mass or less and more preferably 90% by mass or less. Since the in-plane uniformity of a treated wafer can be improved, it is preferable that the Ge concentration is set to be within the above-described range. The reason why it is preferable that Ge has a relatively high concentration is assumed as follows. In a case where Ge is compared with Si, it is understood that an oxide film SiOx is generated after Si is oxidized and the oxides become a reaction-stop layer without being eluted. For this reason, a difference is generated between a portion in which Ge is eluted and a portion in which the reaction is stopped due to SiOx within the wafer and thus the in-plane uniformity of the wafer is damaged. Meanwhile, it is considered that the influence of inhibition of SiOx according to the above-described mechanism becomes decreased when the Ge concentration becomes greater and thus the in-plane uniformity of the wafer can be secured when a liquid chemical with high removability with respect to the metal layer such as the etching solution of the present invention is used. In addition, in a case where the concentration of germanium is 100% by mass, a layer formed along with an alloy of the second layer resulting from the annealing contains germanium and specific metal elements of the second layer and does not contain silicon, but is referred to as germanium silicide layer including the above-described meaning for the sake of convenience in the present specification.

The germanium silicide layer (third layer) is a layer containing germanium (Ge) and the specific metal elements interposed between the first layer and the second layer. The composition thereof is not particularly limited, but “x+y” is preferably in the range of 0.2 to 0.8 and more preferably in the range of 0.3 to 0.7 in the formula of SixGeyMz (M: metal element) when “x+y+z” is set to 1. In a case of z, z is preferably in the range of 0.2 to 0.8 and more preferably in the range of 0.3 to 0.7. The preferable range of the ratio of x to y is as defined above. In this case, the third layer may contain other elements. This point is the same as that described in the section of the metal layer (second layer).

(Processing of MOS Transistor)

FIGS. 2(A) to 2(E) each are a process view illustrating examples of manufacturing a MOS transistor. FIG. 2(A) illustrates a process of forming the structure of the MOS transistor, FIG. 2(B) illustrates a process of sputtering the metal layer, FIG. 2(C) illustrates a first annealing process, FIG. 2(D) illustrates a process of selectively removing the metal layer, and FIG. 2(E)illustrates a second annealing process.

As illustrated in the figures, a gate electrode 23 is formed through a gate insulating film 22 formed on the surface of a silicon substrate 21. Extension regions may be individually formed on both sides of the gate electrode 23 of the silicon substrate 21. A protective layer (not illustrated) that prevents contact with a NiPt layer may be formed on the upper side of the gate electrode 23. Moreover, a side wall 25 formed of a silicon oxide film or a silicon nitride film is formed and a source electrode 26 and a drain electrode 27 are formed by ion implantation.

Next, as illustrated in the figures, a NiPt film 28 is formed and a rapid annealing treatment is performed. In this manner, elements in the NiPt film 28 are allowed to be diffused into the silicon substrate for silicidation. As a result, the upper portion of the source electrode 26 and the drain electrode 27 is silicided and a NiPtGeSi source electrode portion 26A and a NiPtSiGe drain electrode portion 27A are formed. At this time, as illustrated in FIG. 2(E), an electrode member can be changed to be in a desired state by performing the second annealing if necessary. The temperature of the first annealing or the second annealing is not particularly limited, but the annealing can be performed in a temperature range of, for example, 400° C. to 1100° C.

The NiPt film 28 remaining without contributing to silicidation can be removed using the etching solution of the present invention (FIGS. 2(C) and 2(D)). At this time, illustration is made in a greatly schematic manner and the NiPt film remaining by being deposited on the upper portion of the silicided layer (26A and 27A) may or may not be present. The semiconductor substrate or the structure of the product is illustrated in a simplified manner and, if necessary, the illustration may be interpreted that there is a required member.
Silicon substrate 21: Si, SiGe, and Ge
Gate insulating film 22: HfO2 (High-k)
Gate electrode 23: Al, W, TiN, or Ta
Side wall 25: SiOCN, SiN, SiO₂ (low-k)
Source electrode 26: SiGe, Ge, and Si
Drain electrode 27: SiGe, Ge, and Si
Metal layer 28: Ni, Pt, Ti, and Co
Cap (not illustrated): TiN

The semiconductor substrate to which the etching method of the present invention is applied is described above, but the etching method of the present invention can be applied to other semiconductor substrates without being limited to the specific example. For example, a semiconductor substrate including a high dielectric film or a metal gate FinFET which has a silicide pattern on the source region and/or the drain region is exemplified.

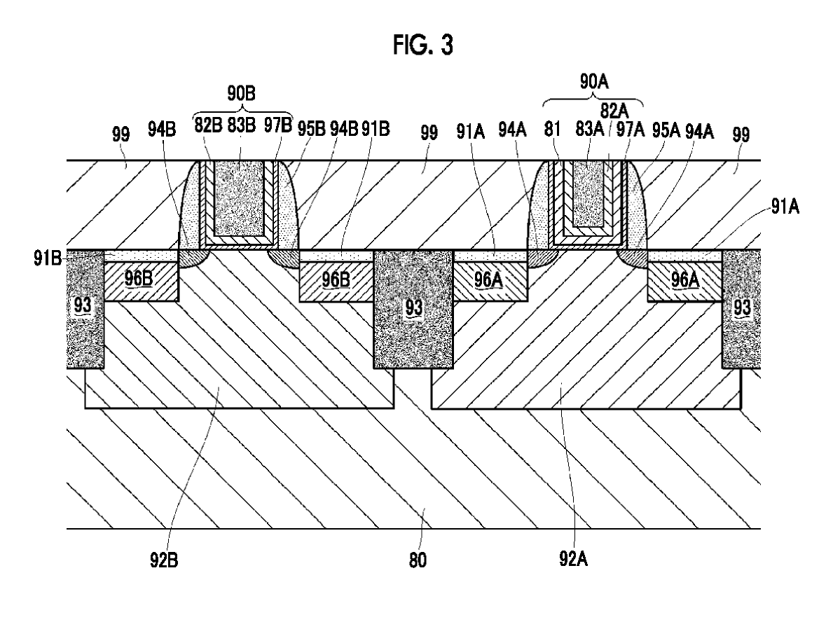

FIG. 3 is a sectional view schematically illustrating a structure of a substrate according to another embodiment of the present invention. The reference numeral 90A indicates a first gate stack positioned in a first device region. The reference numeral 90B indicates a second gate stack positioned in a second element region. Here, the gate stack contains a conductive tantalum alloy layer or TiA1C. When the first gate stack is described, the reference numeral 92A indicates a well. The reference numeral 94A indicates a first source/drain extension region, the reference numeral 96A indicates a first source/drain region, and the reference numeral 91 A indicates a first metal semiconductor alloy portion. The reference numeral 95A indicates a first gate spacer. The reference numeral 97A indicates a first gate insulating film, the reference numeral 81 indicates a first work function material layer, and the reference numeral 82A indicates a second work function material layer. The reference numeral 83A indicates a first metal portion which becomes an electrode. The reference numeral 93 indicates a trench structure portion and the reference numeral 99 indicates a flattened dielectric layer. The reference numeral 80 indicates a lower semiconductor layer.

The first gate stack has the same structure as that of the second gate stack and the reference numerals 91B, 92B, 94B, 95B, 96B, 97B, 82B, and 83B respectively correspond to the reference numerals 91A, 92A, 94A, 95A, 96A, 97A, 82A, and 83A of the first gate stack. When a difference between both structures is described, the first gate stack includes the first work function material layer 81, but the second gate stack is not provided with such a layer.

The work function material layer may be any one of a p type work function material layer or an n type work function material layer. The p type work function material indicates a material having a work function between a valence band energy level and a mid-band gap energy level of silicon. That is, the energy level of a conduction band and the valence band energy level are equivalently separated from each other in the energy level of silicon. The n type work function material indicates a material having a work function between the energy level of the conduction band of silicon and the mid-band gap energy level of silicon.

It is preferable that the material of the work function material layer is a conductive tantalum alloy layer or TiA1C. The conductive tantalum alloy layer can contain a material selected from (i) an alloy of tantalum and aluminum, (ii) an alloy of tantalum and carbon, and (iii) an alloy of tantalum, aluminum, and carbon.

(i) TaAl

In the alloy of tantalum and aluminum, the atom concentration of tantalum can be set to be in the range of 10% to 99%. The atom concentration of aluminum can be set to be in the range of 1% to 90%.

(ii) TaC

In the alloy of tantalum and carbon, the atom concentration of tantalum can be set to be in the range of 20% to 80%. The atom concentration of carbon can be set to be in the range of 20% to 80%.

(iii) TaAlC

In the alloy of tantalum, aluminum, and carbon, the atom concentration of tantalum can be set to be in the range of 15% to 80%. The atom concentration of aluminum can be set to be in the range of 1% to 60%. The atom concentration of carbon can be set to be in the range of 15% to 80%.

In another embodiment, the work function material layer can be set to be (iv) a titanium nitride layer substantively formed of titanium nitride or (v) a layer of an alloy of titanium, aluminum, and carbon.

(iv) TiN

In the titanium nitride layer, the atom concentration of titanium can be set to be in the range of 30% to 90%. The atom concentration of nitrogen can be set to be in the range of 10% to 70%.

(v) TiAlC

In the layer of the alloy of titanium, aluminum, and carbon, the atom concentration of titanium can be set to be in the range of 15% to 45%. The atom concentration of aluminum can be set to be in the range of 5% to 40%. The atom concentration of carbon can be set to be in the range of 5% to 50%.

The work function material layer can be formed by atomic layer deposition (ALD), physical vapor deposition (PVD), or chemical vapor deposition (CVD). It is preferable that the work function material layer is formed so as to cover the gate electrode, and the film thickness thereof is preferably 100 nm or less, more preferably 50 nm or less, and still more preferably in the range of 1 nm to 10 nm.

Among these, in the present invention, it is preferable to use a substrate in which a layer of TiAlC is employed from a viewpoint of suitably expressing selectivity of etching.

In the element of the present embodiment, the gate dielectric layer is formed of a high-k material containing a metal and oxygen. A known material can be used as the high-k gate dielectric material. The layer can be allowed to be deposited using a normal method. Examples thereof include chemical vapor deposition (CVD), physical vapor deposition (PVD), molecular beam deposition (MBD), pulsed laser deposition (PLD), liquid raw material mist chemical deposition (LSMCD), and atomic layer deposition (ALD). Examples of the typical high-k dielectric material include HfO₂, ZrO₂, La₂O₃, Al₂O₃, TiO₂, SrTiO₃, LaAlO₃, Y₂O₃, HfOₓN_{y}, ZrOₓN_{y}, La₂OₓN_{y}, Al₂OₓN_{y}, TiOₓN, SrTiOₓN_{y}, LaAlOₓN_{y}, and Y₂OₓN_{y}. x is in the range of 0.5 to 3 and y is in the range of 0 to 2. The thickness of the gate dielectric layer is preferably in the range of 0.9 nm to 6 nm and more preferably in the range of 1 nm to 3 nm. Among these, it is preferable that the gate dielectric layer is formed of hafnium oxide (HfO₂).

Other members or structures can be formed by a normal method according to appropriate normal materials. Specifically, US2013/0214364A and US2013/0341631A can be referenced and the contents of which are incorporated by reference.

In the etching solution according to the preferred embodiment of the present invention, even in a case of a substrate whose work function material layer described above is exposed, metals (Ni, Pt, Ti, and the like) of the first layer can be effectively removed while suppressing damage of the layer.

[Etching Solution]

Next, a preferred embodiment of the etching solution of the present invention will be described. The etching solution of the present embodiment contains an acid compound and an oxidant as needed. Hereinafter, respective components including arbitrary components will be described below.

(Specific Acid Compound)

Examples of the specific acid compound include sulfuric acid (H₂SO₄), nitric acid (HNO₃), phosphoric acid (H₃PO₄), and phosphoric acid (H₃PO₃), and organic acid.

An organic acid compound having a sulfonic acid group, a carboxyl group, a phosphoric acid group, a phosphonic acid group, or a hydroxamic acid group is preferable as organic acid. The number of carbon atoms of the organic acid compound is preferably in the range of 1 to 24, more preferably in the range of 1 to 16, and particularly preferably in the range of 1 to 8.

It is preferable that the organic acid is formed of a compound represented by the following Formula (O-1).

Ra—(Ac)n (O-1)

Ra represents an alkyl group having 1 to 24 carbon atoms (the number of carbon atoms is preferably in the range of 1 to 16, more preferably in the range of 1 to 12, and particularly preferably in the range of 1 to 8), an alkenyl group having 2 to 24 carbon atoms (the number of carbon atoms is preferably in the range of 2 to 16, more preferably in the range of 2 to 12, and particularly preferably in the range of 2 to 8), an alkynyl group having 2 to 24 carbon atoms (the number of carbon atoms is preferably in the range of 2 to 16, more preferably in the range of 2 to 12, and particularly preferably in the range of 2 to 8), an aryl group 6 to 18 carbon atoms (the number of carbon atoms is preferably in the range of 6 to 14 and more preferably in the range of 6 to 10), or an aralkyl group having 7 to 19 carbon atoms (the number of carbon atoms is preferably in the range of 7 to 15 and more preferably in the range of 7 to 11). When Ra represents an alkyl group, an alkenyl group, or an alkynyl group, for example, O, S, CO, or NR^{N} (the definition of R^{N} will be mentioned later) may be present in a range of 1 to 6. Further, Ra may further include a substituent T and examples of the arbitrary substituent include a hydroxy group, a sulfanyl group, NR^{N}₂, and a halogen atom (a fluorine atom, a chlorine atom, or a bromine atom). The number of arbitrary substituents is preferably in the range of 1 to 6 and more preferably in the range of 1 to 4.

Ac represents a sulfonic acid group, a carboxyl group, a phosphoric acid group, a phosphonic acid group or a hydroxamic acid group. When Ac represents a carboxyl group or a hydroxamic acid group, Ra may represent a hydrogen atom.

n represents an integer of 1 to 4.

Specific examples of the acid compound include compounds described in Example below. These compounds are defined through categorization as compounds which are used in a relatively large amount (large amount series) and compounds which are used in a small amount (small amount series), and the large amount series and the small amount series are listed in Table A below.

TABLE A

| Acidic | | |
|---|---|---|
| compound | Large amount series | Small amount series |
| Inorganic acid | Phosphoric acid, | Nitric acid |
| | phosphonic acid, | |
| | sulfuric acid | |
| Organic acid | Sulfonic acid having | Sulfonic acid having |
| (sulfonic acid) | 1 to 3 carbon atoms, | 4 to 24 carbon atoms, |
| | methanesulfonic acid, | trifluoromethanesulfonic |
| | ethanesulfonic acid, | acid, dodecylsulfonic acid, |
| | ethanedisulfonic acid, | butanesulfonic |
| | methane disulfone | acid, propanesulfonic acid, |
| | acid | (per)fluoroalkylsulfonic acid |
| | | (having 4 or more carbon |
| | | atoms), toluenesulfonic acid, |
| | | cyclohexanesulfonic acid, |
| | | benzylsulfonic acid, |
| | | hydroxyphenylmethanesulfonic |
| | | acid, naphthalenesulfonic acid, |
| | | naphthalenedisulfonic acid |
| Organic acid | Lactic acid, | Citric acid, propionic acid, |
| (carboxylic | acetic acid | malic acid, tartaric acid, |
| acid) | | malonic acid, oxalic acid, |
| | | succinic acid, gluconic |
| | | acid, glycolic acid, diglycolic |
| | | acid, maleic acid, benzoic acid, |
| | | phthalic acid, salicylic acid, |
| | | oxydiacetic acid, formic acid |
| Organic acid | | Salicylic hydroxamic |
| (hydroxamic | | acid, phthalic |
| acid) | | hydroxamic acid |

The categorization of the large amount series and the small amount series may be made in relation to the effects of the present invention, but an evaluation can be generally performed in consideration of the relationship between the melting point of a compound and the solubility of the compound in a solvent being used. Moreover, the large amount series may be used in a small amount depending on the kind of an oxidant to be combined with and a target to be etched (see tests 401 and 407 of Example). Alternatively, the large amount series may be applied at a low concentration in consideration of the strength of etching force (see test 203 of Example).

The concentration of the acid compound contained in the etching solution is preferably 0.01% by mass or greater, more preferably 2% by mass or greater, and particularly preferably 5% by mass or greater. The upper limit thereof is preferably 99% or less, more preferably 95% by mass or less, still more preferably 90% by mass or less, even still more preferably 70% by mass or less, and particularly preferably 60% by mass or less.

When the concentration of the acid compounds is defined by dividing the large amount series and the small amount series from each other, the concentration of the large amount series is preferably 25% by mass or greater, more preferably 50% by mass or greater, and particularly preferably 70% by mass or greater. The upper limit thereof is preferably 99% by mass or less, more preferably 95% by mass or less, and particularly preferably 90% by mass or less.

The concentration of the small amount series is preferably 0.01% by mass or greater, more preferably 0.1% by mass or greater, and particularly preferably 1% by mass or greater. The upper limit thereof is preferably less than 50% by mass, more preferably 40% by mass or less, and particularly preferably 35% by mass or less.

It is preferable that the concentration of the acid compound is set to be in the above-described range because damage (surface roughening) of the germanium-containing layer (first layer) or the germanium silicide layer (third layer) can be effectively suppressed while excellent etching properties of the metal layer (second layer) are maintained. In regard to identification of components of the etching solution, it is not necessary for the components thereof to be confirmed as acid compounds. For example, in a case of nitric acid, when sulfuric acid ions (SO₄²⁻) in an aqueous solution are identified, the presence and the amount thereof are grasped.

Moreover, in the present invention, the acid compounds may be used alone or in combination of two or more kinds thereof. In the case where the acid compounds are used in combination of two or more kinds thereof, the combining ratio is not particularly limited, but the total amount used thereof is preferably in the above-described range of concentration as the sum of two or more kinds of acid compounds. Further, a preferable combination of two or more kinds thereof is a combination of compounds exemplified in the “large amount series” or a combination of compounds exemplified in the “small amount series,” but compounds of the “large amount series” and the “small amount series” can be combined with each other as long as the effects of the present invention are exhibited.

(Oxidant)

It is preferable that the etching solution according to the present embodiment contains an oxidant. Preferred examples of the oxidant include nitric acid and hydrogen peroxide.

The concentration of the oxidant contained in the etching solution is preferably 0.1% by mass or greater, more preferably 1% by mass or greater, and particularly preferably 2% by mass or greater. The upper limit thereof is preferably 50% by mass or less, more preferably 45% by mass or less, and particularly preferably 35% by mass or less.

It is preferable that the concentration of the oxidant is set to be in the above-described range because damage of the germanium-containing layer (first layer) or the germanium silicide layer (third layer) can be effectively suppressed while excellent etching properties of the metal layer (second layer) are maintained. In regard to identification of components of the etching solution, it is not necessary for the components thereof to be confirmed as nitric acid. For example, when nitric acid ions (NO₃⁻) in an aqueous solution are identified, the presence and the amount thereof are grasped. Moreover, the oxidant may be used alone or in combination of two or more kinds thereof.

The display of compounds in the present specification (for example, when a compound is referred to by being added at the end of the compound) is used to include the compound itself, a salt thereof, and an ion thereof. Further, the display thereof includes a derivative which is partially changed by being esterified or introducing a substituent within a range in which desired effects can be exhibited.

A substituent (the same applies to a linking group) in which substitution or unsubstitution is not specified in the present specification means that an arbitrary substituent may be included in the group. The same applies to a compound in which substitution or unsubstitution is not specified. As a preferred substituent, the substituent T described below is exemplified.

Examples of the substituent T include the followings.

An alkyl group (preferably an alkyl group having 1 to 20 carbon atoms such as methyl, ethyl, isopropyl, t-butyl, pentyl, heptyl, 1-ethylpentyl, benzyl, 2-ethoxyethyl, or 1-carboxymethyl), an alkenyl group (preferably, an alkenyl group having 2 to 20 carbon atoms such as vinyl, allyl, or oleyl), an alkynyl group (preferably an alkynyl group having 2 to 20 carbon atoms such as ethynyl, butadiynyl, or phenylethynyl), a cycloalkyl group (preferably a cycloalkyl group having 3 to 20 carbon atoms such as cyclopropyl, cyclopentyl, cyclohexyl, or 4-methylcyclohexyl), an aryl group (preferably an aryl group having 6 to 26 carbon atoms such as phenyl, 1-naphthyl, 4-methoxyphenyl, 2-chlorophenyl, or 3-methylphenyl), a heterocyclic group (preferably a heterocyclic group having 2 to 20 carbon atoms or preferably a heterocycle of a 5- or 6-membered ring having at least one of an oxygen atom, a sulfur atom and a nitrogen atom such as 2-pyridyl, 4-pyridyl, 2-imidazolyl, 2-benzimidazolyl, 2-thiazolyl, or 2-oxazolyl), an alkoxy group (preferably an alkoxy group having 1 to 20 carbon atoms such as methoxy, ethoxy, isopropyloxy, or benzyloxy), an aryloxy group (preferably an aryloxy group having 6 to 26 carbon atoms such as phenoxy, 1-naphthyloxy, 3-methylphenoxy, or 4-methoxyphenoxy), an alkoxycarbonyl group (preferably an alkoxycarbonyl group having 2 to 20 carbon atoms such as ethoxycarbonyl or 2-ethylhexyloxycarbonyl), an amino group (preferably an amino group having 0 to 20 carbon atoms, an alkylamino group having 0 to 20 carbon atoms, or an arylamino group having 0 to 20 carbon atoms such as amino, N,N-dimethylamino, N,N-diethylamino, N-ethylamino, or anilino), a sulfamoyl group (preferably a sulfamoyl group having 0 to 20 carbon atoms such as N,N-dimethylsulfamoyl or N-phenylsulfamoyl), an acyl group (preferably an acyl group having 1 to 20 carbon atoms such as acetyl, propionyl, butyryl, or benzoyl), an acyloxy group (preferably an acyloxy group having 1 to 20 carbon atoms such as acetyloxy or benzoyloxy), a carbamoyl group (preferably a carbamoyl group having 1 to 20 carbon atoms such as NN-dimethylcarbamoyl or N-phenylcarbamoyl), an acylamino group (preferably an acylamino group having 1 to 20 carbon atoms such as acetylamino or benzoylamino), a sulfonamide group (preferably a sulfamoyl group having 0 to 20 carbon atoms such as methanesulfonamide, benzenesulfonamide, N-methylmethanesulfonamide, or N-ethylbenzenesulfonamide), an alkylthio group (preferably an alkylthio group having 1 to 20 carbon atoms such as methylthio, ethylthio, isopropylthio, or benzylthio), an arylthio group (preferably an arylthio group having 6 to 26 carbon atoms such as phenylthio, 1-naphthylthio, 3-methylphenylthio, or 4-methoxyphenylthio), alkyl or an arylsulfonyl group (preferably alkyl or an arylsulfonyl group having 1 to 20 carbon atoms such as methylsulfonyl, ethylsulfonyl, or benzenesulfonyl), a hydroxyl group, a cyano group, and a halogen atom (such as a fluorine atom, a chlorine atom, a bromine atom, or an iodine atom). Among these, an alkyl group, an alkenyl group, an aryl group, a heterocyclic group, an alkoxy group, an aryloxy group, an alkoxycarbonyl group, an amino group, an acylamino group, a hydroxyl group or a halogen atom is more preferable. Further, an alkyl group, an alkenyl group, a heterocyclic group, an alkoxy group, an alkoxycarbonyl group, an amino group, an acylamino group, or a hydroxyl group is particularly preferable.

Moreover, respective groups exemplified in these substituents T may be further substituted with the above-described substituents T.

When a compound or a substituent/a linking group include an alkyl group/an alkylene group, an alkenyl group/an alkenylene group, or an alkynyl group/an alkynylene group, these may be cyclic, chain-like, linear, or branched and may be substituted or unsubstituted as described above. Moreover, when an aryl group and a heterocyclic group are included, these may be a single ring or a condensed ring and may be substituted or unsubstituted.

(Aqueous Medium)

In the embodiment, water (aqueous medium) may be used as a medium of the etching solution of the present invention. An aqueous medium containing dissolved components within a range not damaging the effects of the present invention may be used as water (aqueous medium) or water may contain a small amount of inevitable mixing components. Among these, water subjected to a purification treatment such as distilled water, ion-exchange water, or ultrapure water is preferable and ultrapure water to be used for manufacturing a semiconductor is particularly preferable.

(Kit)

The etching solution in the present invention may be used for a kit obtained by dividing the raw material of the etching solution into plural parts. For example, an aspect in which a liquid composition containing the above-described acid compound in water as a first liquid is prepared and a liquid composition containing the above-described specific organic additive in an aqueous medium as a second liquid is prepared is exemplified.

As the usage example, an aspect of preparing an etching solution by mixing both of the liquids and then using the etching solution for the etching treatment at a suitable time is preferable. In this manner, deterioration of liquid performance due to decomposition of respective components is not caused and a desired etching action can be effectively exhibited. Here, the term “suitable time” after mixing both of the liquids indicates a period during which a desired action is lost after the mixing, and, specifically, the period is preferably within 60 minutes, more preferably within 30 minutes, still more preferably within 10 minutes, and particularly preferably within 1 minute. The lower limit thereof, which is not particularly limited, is substantively 1 second or longer.

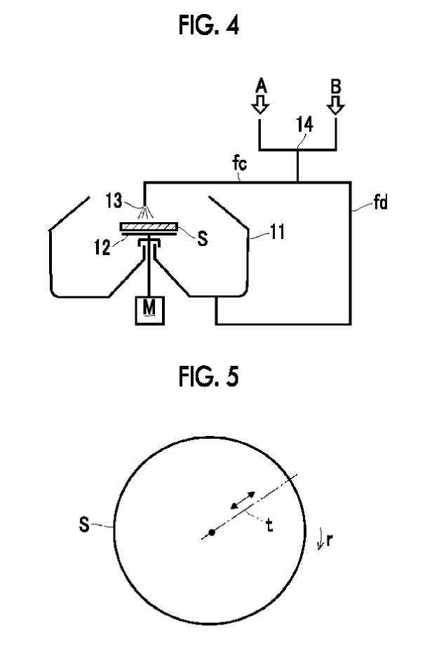

The manner of mixing the first liquid and the second liquid is not particularly limited, but the mixing is preferably performed by circulating the first liquid and the second liquid in different channels and merging both of the liquids at a junction point. Subsequently, both of the liquids are circulated through the channels, an etching solution obtained after both of the liquids are merged is ejected or sprayed from an ejection opening, and the etching solution is brought into contact with a semiconductor substrate. In the embodiment, it is preferable that the process from which both of the liquids are merged and mixed with each other at the junction point to which the solution is brought into contact with the semiconductor substrate is performed at the suitable time described above. When this process is described with reference to FIG. 4, the prepared etching solution is sprayed from an ejection opening 13 and then applied to the upper surface of a semiconductor substrate S in a treatment container (treatment tank) 11. In the embodiment shown in the same figure, two liquids of A and B are supplied to be merged with each other at a junction point 14 and then the liquids are transitioned to the ejection opening 13 through a channel fc. A channel fd indicates a returning path for reusing a liquid chemical. It is preferable that the semiconductor substrate S is on a rotary table 12 and rotates along with the rotary table by a rotation driving unit M. In addition, in the embodiment in which such a substrate rotation type device is used, the same applies to a treatment using the etching solution which is not used for a kit.

Moreover, in the etching solution of the present invention, it is preferable that the amount of impurities in the solution, for example, metals is small when the usage of the etching solution is considered. Particularly, the ion concentration of Na, K, and Ca in the solution is preferably in the range of 1 ppt to 1 ppm (on a mass basis). Further, in the etching solution, the number of coarse particles having an average particle diameter of 0.5 μm or greater is preferably 100/cm³ or less and more preferably 50/cm³.

(Container)

The etching liquid of the present invention fills an arbitrary container to be stored, transported, and then used as long as corrosion resistance is not a problem (regardless of the container being a kit or not). Further, a container whose cleanliness is high and in which the amount of impurities to be eluted is small is preferable for the purpose of using the container for a semiconductor. As a usable container, “Clean bottle” series (manufactured by ACELLO CORPORATION) or “Pure bottle” (manufactured by KODAMA PLASTICS Co., Ltd.) is exemplified, but the examples are not limited thereto.

[Etching Conditions]

In an etching method of the present invention, it is preferable to use a sheet type device. Specifically, a sheet type device which has a treatment tack and in which the semiconductor substrate is transported or rotated in the treatment tank, the etching solution is provided (ejection, spray, falling, dropping, or the like) in the treatment tank, and the etching solution is brought into contact with the semiconductor substrate is preferable.

Advantages of the sheet type device are as follows: (i) a fresh etching liquid is constantly supplied and thus reproducibility is excellent and (ii) in-plane uniformity is high. Further, a kit obtained by dividing the etching liquid into plural parts is easily used and, for example, a method of mixing the first and second liquids with each other in line and ejecting the liquid is suitably employed. At this time, a method of mixing the liquids with each other in line and ejecting the mixed solution after the temperature of both of the first liquid and the second liquid is adjusted or the temperature of one of the first liquid and the second liquid is adjusted is preferable. Between the two, adjusting the temperature of both liquids is more preferable. It is preferable that the managed control at the time of adjusting the temperature of the line is set to be in the same range as that of the treatment temperature described below.

The sheet type device is preferably provided with a nozzle in the treatment tank thereof and a method of ejecting the etching solution to the semiconductor substrate by swinging the nozzle in the plane direction of the semiconductor substrate is preferable. In this manner, deterioration of the solution can be prevented, which is preferable. Further, the solution is separated into two or more liquids after the kit is prepared and thus gas or the like is unlikely to be generated, which is preferable.

The treatment temperature of performing etching is preferably 20° C. or higher and more preferably 30° C. or higher. The upper limit thereof is preferably 80° C. or lower, more preferably 70° C. or lower, and still more preferably 60° C. or lower. It is preferable that the temperature is set to be higher than or equal to the lower limit because the etching rate with respect to the second layer can be sufficiently secured. It is preferable that the temperature thereof is set to be lower than or equal to the upper limit thereof because stability over time for the rate of the etching treatment can be maintained. In addition, when the etching treatment is carried out at around room temperature, this leads to a reduction of energy consumption.

The rate of supplying the etching solution, which is not particularly limited, is preferably in the range of 0.05 L/min to 5 L/min and more preferably in the range of 0.1 L/min to 3 L/min. It is preferable that the rate thereof is set to be greater than or equal to the lower limit because the in-plane uniformity of etching can be more excellently secured. It is preferable that the rate thereof is set to be less than or equal to the upper limit because the performance stabilized at the time of performing a treatment continuously can be secured. The rotation of the semiconductor substrate also depends on the size thereof and the semiconductor substrate rotates preferably at 50 rpm to 1000 rpm from the same viewpoint described above.

In sheet type etching according to the preferred embodiment of the present invention, it is preferable that the semiconductor substrate is transported or rotated in a predetermined direction and an etching solution is brought into contact with the semiconductor substrate by spraying the etching solution to the space of the semiconductor substrate. The rate of supplying the etching solution and the rotation rate of the substrate are the same as those described above.

In the configuration of the sheet type device according to the preferred embodiment of the present invention, it is preferable that the etching solution is provided while the ejection opening (nozzle) is moved as illustrated in FIG. 5. Specifically, in the present embodiment, the substrate is rotated in an r direction when the etching solution is applied to the semiconductor substrate S. Further, the ejection opening is set to move along a movement locus line t extending to the end portion from the central portion of the semiconductor substrate. In this manner, the rotation direction of the substrate and the movement direction of the ejection opening are set to be different from each other in the present embodiment and thus both directions are set to be relatively moved. As a result, the etching solution can be evenly provided for the entire surface of the semiconductor substrate and the uniformity of etching is suitably secured.

The moving speed of the ejection opening (nozzle), which is not particularly limited, is preferably 0.1 cm/s or greater and more preferably 1 cm/s or greater. The upper limit thereof is preferably 30 cm/s or less and more preferably 15 cm/s or less. The movement locus line may be linear or curved (for example, ark-shaped). In both cases, the movement speed can be calculated from the distance of an actual locus line and the time spent for the movement thereof. The time required for etching one sheet of substrate is preferably in the range of 10 seconds to 180 seconds.

It is preferable that the metal layer is etched at a high etching rate. An etching rate [R2] of the second layer (metal layer), which is not particularly limited, is preferably 20 Å/min or greater, more preferably 40 Å/min or greater, still more preferably 100 Å/min, and particularly preferably 200 Å/min or greater in terms of productivity. The upper limit, which is not particularly limited, is substantively 1200 Å/min or less.

The exposure width of the metal layer, which is not particularly limited, is preferably 2 nm or greater and more preferably 4 nm or greater from a viewpoint that the advantages of the present invention become remarkable. The upper limit thereof is substantively 1000 nm or less, preferably 100 nm or less, and more preferably 20 nm or less from a viewpoint that the effects thereof become significant in the same manner.

An etching rate [R1] of the layer (first layer) containing germanium or the silicide layer is not particularly limited, but it is preferable that the layer is not excessively removed. The etching rate thereof is preferably 50 Å/min or less, more preferably 20 Å/min or less, and particularly preferably 10 Å/min or less. The lower limit thereof, which is not particularly limited, is substantively 0.1 Å/min or greater when the measurement limit is considered.

In the selective etching of the first layer, the ratio of the etching rate ([R2]/[R1]), which is not particularly limited, is preferably 2 or greater, more preferably 10 or greater, and still more preferably 20 or greater from a viewpoint of elements which need high selectivity. The upper limit thereof, which is not particularly limited, is preferred as the value becomes larger, but the upper limit thereof is substantively 5000 or less. Further, the etching behavior of the germanium silicide layer (third layer) is in common with a layer (for example, a first layer of a SiGe or Ge layer) before annealing is applied thereto. Accordingly, the etching rate or the state of surface roughness can be substituted according to the evaluation of the first layer.

[Manufacturer of Semiconductor Substrate Product (Semiconductor Process)]

In the present embodiment, on a silicon wafer, it is preferable that a semiconductor substrate product having a desired structure is manufactured through a process of preparing a semiconductor substrate on which the silicon layer and the metal layer are formed, a process of annealing the semiconductor substrate, and a process of providing the etching solution for the semiconductor substrate such that the etching solution is brought into contact with the metal layer and selectively removing the metal layer. At this time, the specific etching solution is used for etching. The order of the processes is not limited and other processes may be further included between respective processes.

The size of a wafer is not particularly limited, but a wafer whose diameter is 8 inches, 12 inches, or 14 inches is preferably used.

### EXAMPLES

Hereinafter, the present invention will be specifically described with reference to Examples, but the present invention is not limited to Examples described below.

(Preparation of Silicide-Processed Substrate)

SiGe was epitaxially grown on a commercially available silicon substrate (diameter: 12 inches) and a Pt/Ni metal layer (thickness: 20 nm, ratio of Pt/Ni: 10/90 (on a mass basis)) was subsequently formed. At this time, the SiGe epitaxial layer contained 50% by mass to 60% by mass of germanium. The semiconductor substrate was annealed at 800° C. for 10 seconds and a germanium silicide layer was formed to be used as a test substrate. The thickness of the annealed germanium silicide layer was 15 nm and the thickness of the metal layer was 5 nm.

(Etching Test)

The etching was performed under the following conditions in a sheet type device (POLOS (trade name), manufactured by SPS-Europe B. V.)) with respect to the substrate for a test and an evaluation test was carried out.
Treatment temperature: 40° C.
Ejection amount: 1 L/min
Wafer rotation speed: 500 rpm
Nozzle movement speed: 7 cm/s

Further, the etching solution was supplied by being separated into two liquids as described below to be line mixed (see FIG. 4). A supply line fc was heated such that the temperature thereof was adjusted to 60° C.
First liquid (A): acid compound and water
Second liquid (B): oxidant and water

The ratio of the first liquid to the second liquid was set such that the amounts thereof were substantially the same as each other in terms of the volume. According to the formulation, when an acid compound was singly used, a treatment using only one liquid was carried out in this case.

(Method of Measuring Treatment Temperature)

A radiation thermometer IT-550F (trade name, manufactured by HORIBA, Ltd.) was fixed to a position having a height of 30 cm on a wafer in the sheet type device. The thermometer was directed to the surface of the wafer outside from the center thereof by a distance of 2 cm and the temperature was measured while circulating a liquid chemical. The temperature was continuously recorded using a computer through digital output from the radiation thermometer. Among these, a value obtained by averaging the recorded values of the temperature for 10 seconds at the time when the temperature thereof was stabilized was set as a temperature on the wafer.

(Etching Rate)

The etching rate (ER) was calculated by measuring the film thickness before and after the etching treatment using the following device. The average value of five points was adopted.

Film thickness measuring method: A film thickness measuring method using a four-terminal method was adopted. As the device, VR-120S (trade name, manufactured by Hitachi Kokusai Electric Inc.) was used.

(Ge Concentration)

In the substrate of the first layer containing germanium (Ge), a depth direction of 0 nm to 30 nm was analyzed using etching ESCA (Quantera, manufactured by ULVAC-PHI, INC.) and the average value of the Ge concentration in the analysis results at 3 nm to 15 nm was set as Ge concentration (% by mass).

(Roughness of Surface of Suicide Layer)

The surface of the substrate after etching was observed using a scanning electron microscope (SEM). As a result of observation by extracting five points, the state of surface roughness was confirmed through visual observation in average three points based on the following criteria. The panel was composed of five people and the evaluation was made from the results of the average of three people.
3: Color unevenness was not found
2: Color unevenness was slightly found
1: Color unevenness was found

TABLE 1

| | | | | | | Evaluation result | |
|---|---|---|---|---|---|---|---|
| | Component of liquid chemical | | | | | NiPt | NiPtSiGe |
| | | % by | | % by | | ER | surface |
| Test | Acid | mass | Oxidant | mass | Water | (Å/min.) | roughness |
| 101 | Phosphoric acid | 85 | — | — | Remainder | 100 | 3 |
| 102 | Phosphonic acid | 80 | — | — | Remainder | 70 | 3 |
| 103 | Methanesulfonic acid | 75 | — | — | Remainder | 110 | 3 |
| 104 | Ethanesulfonic acid | 76 | — | — | Remainder | 60 | 3 |
| 105 | Methanedisulfonic acid | 75 | — | — | Remainder | 70 | 3 |
| 106 | Ethanedisulfonic acid | 77 | — | — | Remainder | 80 | 3 |
| 107 | Lactic acid | 75 | — | — | Remainder | 110 | 3 |
| 108 | Acetic acid | 80 | — | — | Remainder | 90 | 3 |
| 109 | Sulfuric acid | 80 | — | — | Remainder | 72 | 3 |
| 201 | Trifluoromcthancsulfonic acid | 3 | — | — | Remainder | 60 | 3 |
| 202 | Dodecylsulfonic acid | 5 | — | — | Remainder | 50 | 3 |
| 203 | Nitric acid | 10 | — | — | Remainder | 100 | 3 |
| 204 | Gluconic acid | 7 | — | — | Remainder | 70 | 3 |
| 205 | Glycolic acid | 15 | — | — | Remainder | 60 | 3 |
| 206 | p-toluenesulfonic acid | 5 | — | — | Remainder | 70 | 3 |
| 207 | Perfluorobutanesulfonic acid | 3 | — | — | Remainder | 80 | 3 |
| 208 | Cyclohexanesulfonic acid | 4 | — | — | Remainder | 60 | 3 |
| 209 | Butanesulfonic acid | 6 | — | — | Remainder | 50 | 3 |
| 210 | Bcnzylsulfonic acid | 14 | — | — | Remainder | 90 | 3 |
| 211 | Hydroxyphenylmethanesulfonic acid | 13 | — | — | Remainder | 50 | 3 |
| 212 | Naphthalcncsulfonic acid | 0.5 | — | — | Remainder | 60 | 3 |
| 213 | 3,5-naphthalenesulfonic acid | 0.9 | — | — | Remainder | 80 | 3 |
| 214 | Citric acid | 2 | — | — | Remainder | 70 | 3 |
| 215 | Propionic acid | 1 | — | — | Remainder | 70 | 3 |
| 216 | Malic acid | 5 | — | — | Remainder | 70 | 3 |
| 217 | Tartaric acid | 5 | — | — | Remainder | 60 | 3 |
| 218 | Malonic acid | 4 | — | — | Remainder | 50 | 3 |
| 219 | Oxalic acid | 6 | — | — | Remainder | 60 | 3 |
| 220 | Succinic acid | 4 | — | — | Remainder | 60 | 3 |
| 221 | Diglycolic acid | 8 | — | — | Remainder | 50 | 3 |
| 222 | Maleic acid | 1 | — | — | Remainder | 50 | 3 |
| 223 | Benzoic acid | 0.4 | — | — | Remainder | 70 | 3 |
| 224 | Phthalic acid | 0.5 | — | — | Remainder | 50 | 3 |
| 225 | Salicylic acid | 1 | — | — | Remainder | 60 | 3 |
| 226 | Salicylic hydroxamic acid | 0.5 | — | — | Remainder | 70 | 3 |
| 227 | Phthalic hydroxamic acid | 1 | — | — | Remainder | 80 | 3 |
| 228 | Ethylene dioxy diatetic acid | 0.1 | — | — | Remainder | 60 | 3 |
| 229 | Formic acid | 5 | — | — | Remainder | 50 | 3 |
| 301 | Methanesulfonic acid | 75 | Hydrogen peroxide | 5 | Remainder | 120 | 3 |
| 302 | Acetic acid | 75 | Hydrogen peroxide | 5 | Remainder | 150 | 3 |
| 303 | Lactic acid | 60 | Hydrogen peroxide | 5 | Remainder | 110 | 2 |
| 401 | Phosphoric acid | 3 | Hydrogen peroxide | 10 | Remainder | 100 | 3 |
| 402 | Citric acid | 10 | Hydrogen peroxide | 7 | Remainder | 130 | 3 |
| 403 | Oxalic acid | 7 | Hydrogen peroxide | 8 | Remainder | 140 | 3 |
| 404 | Salicylic acid | 15 | Hydrogen peroxide | 15 | Remainder | 100 | 3 |
| 405 | Diglycolic acid | 5 | Hydrogen peroxide | 20 | Remainder | 110 | 3 |
| 406 | Phosphoric acid | 29 | Nitric acid | 30 | Remainder | 130 | 2 |
| 407 | Oxalic acid | 40 | Nitric acid | 30 | Remainder | 110 | 2 |
| 408 | Glycolic acid | 45 | Hydrogen peroxide | 10 | Remainder | 110 | 2 |
| c11 | Hydrochloric acid | 1 | — | — | Remainder | 10 | 3 |
| c12 | Hydrochloric acid | 10 | — | — | Remainder | 50 | 1 |
| c13 | Hydrochloric acid | 1 | Nitric acid | 15 | Remainder | 100 | 1 |

ER: etching rate (Å/min)

According to the present invention, it is understood that the second layer containing a specific metal can be selectively removed with respect to the first layer containing germanium and thus the surface roughness of the germanium-containing layer can be suppressed.

### EXPLANATION OF REFERENCES

1: metal layer (second layer)

2: silicon layer (first layer)

3: silicide layer (third layer)

11: treatment container (treatment tank)

12: rotary table

13: ejection opening

14: junction point

S: substrate

21: silicon substrate

22: gate insulating film

23: gate electrode

25: side wall

26: source electrode

27: drain electrode

28: NiPt film

90A, 90B: replacement gate stack

92A, 92B: well

94A, 94B: source/drain extension region

96A, 96B: source/drain region

91A, 91B: metal semiconductor alloy portion

95A, 95B: gate spacer

97A, 97B: gate insulting film

81: first work function material layer

82A, 82B: second work function material layer

83A, 83B: metal portion

93: trench structure portion

99: flattened dielectric layer

The present invention has been described with reference to the embodiments, but the detailed description of the invention is not intended to limit the invention unless otherwise noted and the present invention should be broadly interpreted without departing from the spirit and the scope described in the aspects of the invention.

What is claimed is:

1. An etching solution of a semiconductor substrate that includes a first layer containing germanium (Ge) and a second layer containing a specific metal element other than germanium (Ge), the etching solution selectively removing the second layer and comprising following specific acid compound.
Specific acid compound: sulfuric acid (H₂SO₄), nitric acid (HNO₃), phosphoric acid (H₃PO₄), phosphonic acid (H₃PO₃), or organic acid

2. The etching solution according to claim 1, wherein the concentration of germanium (Ge) of the first layer is 40% by mass or greater.

3. The etching solution according to claim 1, wherein a metal element constituting the second layer is selected from nickel platinum (NiPt), titanium (Ti), nickel (Ni), and cobalt (Co).

4. The etching solution according to claim 1, wherein the organic acid is organic acid which contains a sulfonic acid group, a carboxy group, a phosphoric acid group, a phosphonic acid group, or a hydroxamic acid group.

5. The etching solution according to claim 1, wherein the content of those in a small amount series among the acid compounds is in the range of 0.01% by mass to less than 50% by mass and the content of those in a large amount series among the acid compounds is in the range of 25% by mass to 99% by mass.

6. The etching solution according to claim 1, wherein the second layer is selectively removed with respect to the first layer and/or the following third layer.
Third layer: layer containing germanium (Ge) and the specific metal element, which is interposed between the first layer and the second layer

7. The etching solution according to claim 1, further comprising an oxidant.

8. An etching solution kit of a semiconductor substrate that includes a first layer containing germanium (Ge) and a second layer containing a metal element, the kit selectively removing the second layer and comprising:
a first liquid containing the following specific acid compound; and
a second liquid containing an oxidant.
Specific acid compound: sulfuric acid (H₂SO₄), nitric acid (HNO₃), phosphoric acid (H₃PO₄), phosphonic acid (H₃PO₃), or organic acid

9. An etching method of a semiconductor substrate that includes a first layer containing germanium (Ge) and a second layer containing at least one specific metal element selected from nickel platinum (NiPt), titanium (Ti), nickel (Ni), and cobalt (Co), the method comprising:
bringing an etching solution which contains the following specific acid compound into contact with the second layer and selectively removing the second layer.
Specific acid compound: sulfuric acid (H₂SO₄), nitric acid (HNO₃), phosphoric acid (H₃PO₄), phosphonic acid (H₃PO₃), or organic acid

10. The etching method according to claim 9, wherein the concentration of germanium (Ge) of the first layer is 40% by mass or greater.

11. The etching method according to claim 9, wherein the acid compound is inorganic acid or organic acid which contains a sulfonic acid group, a carboxylic group, a phosphoric acid group, a phosphonic acid group, or a hydroxamic acid group.

12. The etching method according to claim 9, wherein the content of a small amount series among the acid compounds is in the range of 0.01% by mass to less than 50% by mass and the content of a large amount series among the acid compounds is in the range of 25% by mass to 99% by mass.

13. The etching method according to claim 9, wherein the second layer is selectively removed with respect to the first layer and/or the following third layer.
Third layer: layer containing germanium (Ge) and the specific metal element, which is interposed between the first layer and the second layer

14. The etching method according to claim 9, further comprising:
allowing the semiconductor substrate to rotate and supplying the etching solution through a nozzle from the upper surface of the semiconductor substrate during rotation when the etching solution is provided for the semiconductor substrate.

15. The etching method according to claim 9, wherein the temperature of the etching solution at the time of being brought into contact with the second layer is in the range of 20° C. to 80° C.

16. The etching method according to claim 9,
wherein the etching solution further contains an oxidant, and
a first liquid which does not contain the oxidant and a second liquid which contains the oxidant are separated from each other and then stored.

17. The etching method according to claim 16, wherein the first liquid and the second liquid are mixed with each other at a suitable time when the semiconductor substrate is etched.

18. A production method for a semiconductor substrate product that includes a first layer containing germanium (Ge), comprising:
a step of forming at least the first layer and at least one kind of second layer selected from nickel platinum (NiPt), titanium (Ti), nickel (Ni), and cobalt (Co) on the semiconductor substrate;
a step of forming a third layer containing components of the first layer and the second layer between both layers by heating the semiconductor substrate;
a step of preparing an etching solution containing an acid compound; and
a step of bringing the etching solution into contact with the second layer and selectively removing the second layer with respect to the first layer and the third layer.
